(19) United States
(12) Patent Application Publication
(10) Pub. No.: US 2011/0168673 A1
(43) Pub. Date: Jul. 14, 2011

(54) PLASMA PROCESSING APPARATUS, PLASMA PROCESSING METHOD, AND MECHANISM FOR REGULATING TEMPERATURE OF DIELECTRIC WINDOW

(75) Inventor: Shinya Nishimoto, Hyogo (JP)

(73) Assignee: Tokyo Electron Limited, Tokyo (JP)

(21) Appl. No.: 13/002,407

(22) PCT Filed: Jul. 1, 2009
(86) PCT No.: PCT/JP2009/062065

§ 371 Date: Jan. 19, 2011

(30) Foreign Application Priority Data
Jul. 4, 2008 (JP) 2008-175589

(51) Int. Cl. C23F 1/00; C23F 1/08; C23C 16/455; C23C 16/511; C23C 16/52

(52) U.S. Cl. 216/67; 156/345.36; 156/345.27; 118/723 AN; 118/666; 427/569

(57) ABSTRACT

Provided are a plasma processing apparatus, a plasma processing method, and a mechanism for regulating a temperature of a dielectric window, which can achieve a better plasma processing characteristic by more precisely controlling the temperature of the dielectric window through which a microwave used for plasma processing is transmitted. The plasma processing apparatus is provided with a processing container, a dielectric window (shower plate), an antenna, a waveguide, a cooling block, a substrate holder, and a holding ring (upper plate) attached to the upper portion of the processing container. A circumferential portion of the dielectric window is engaged with the holding ring. The cooling block provided with a cooling flow path through which a heat medium can flow is provided on the antenna. A temperature sensor is provided around the waveguide, and a temperature of the antenna or the like is detected. A lamp heater is provided in an inside of the holding ring. The dielectric window is controlled to have a predetermined temperature distribution, by a cooling means of the cooling block and a heating means of the holding ring which are controlled by a control means.

### TECHNICAL FIELD

The present invention relates to a plasma processing apparatus, a plasma processing method, and a mechanism for regulating a temperature of a dielectric window.

### BACKGROUND ART

In a semiconductor manufacturing process, plasma processing is widely performed for the purpose of thin film deposition, etching, or the like. In order to obtain a semiconductor with high performance and high function, uniform plasma processing is required to be performed on an entire surface to be processed of a substrate to be processed in a space with a high degree of cleanness. Such a requirement is further increased as substrates get larger.

At present, a method of exciting a process gas by using a microwave is widely used as a method for generating plasma in plasma processing. A microwave has the property of being transmitted through a dielectric. A microwave can be irradiated into a plasma processing apparatus by providing a window (hereinafter, referred to as a dielectric window), which is formed of a dielectric material and through which a microwave is transmitted, in the plasma processing apparatus. When a process gas introduced into the plasma processing apparatus is excited by the microwave, plasma is generated. In this configuration, since a discharge electrode does not need to be provided in the plasma processing apparatus, the degree of cleanness in the processing device is kept high. Also, in this method, high-density plasma can be formed even at a relatively low temperature, productivity or energy efficiency is excellent.

In this method, since high-density plasma is formed in a space near the dielectric window, the dielectric window is exposed to a lot of ions or electrons. Also, heat is also generated from an antenna which supplies the microwave. Accordingly, if plasma processing is performed for a long time, heat is accumulated on the dielectric window. Overheating of the dielectric window may cause undesirable results, for example, changing the efficiency in exciting process gas or decomposing the process gas.

In order to prevent overheating of the dielectric window, for example, Patent Document 1 discloses a plasma processing apparatus including a processing container, a microwave antenna including a cooling portion, a shower plate formed of a dielectric material, and a cover plate formed of a dielectric material and disposed between the microwave antenna and the shower plate. The plasma processing apparatus prevents overheating of the dielectric window by disposing the microwave antenna, which includes the cooling portion, to be close to the shower plate with the cover plate therebetween.

[Patent Document 1] Japanese Laid-Open Patent Publication No. 2002-299330

### DISCLOSURE OF THE INVENTION

### Technical Problem

However, even in the apparatus disclosed in Patent Document 1, if plasma processing is performed for a long time, a temperature distribution in the dielectric window is greatly skewed and furthermore thermal strain occurs on the dielectric window, thereby changing a characteristic of the apparatus and making it difficult to perform uniform plasma processing. In order to improve a plasma processing characteristic of the plasma processing apparatus, it is not enough only to prevent overheating of the dielectric window, and it is important to make a temperature distribution of the dielectric window uniform, as found in experiments and the like by inventors.

The present invention is proposed considering the state of the art. According to the present invention, there are provided a plasma processing apparatus, a plasma processing method, and a mechanism for regulating a temperature of a dielectric window used for plasma processing, where a better plasma processing characteristic can be achieved by making a temperature distribution of the dielectric window uniform.

### Technical Solution

In order to achieve the objective, a plasma processing apparatus according to an aspect of the present invention includes: a processing container which includes a dielectric window formed of a dielectric material and of which an inside is depressurizable; an antenna which supplies a microwave into the processing container through the dielectric window; a gas supply means which supplies a process gas into the processing container; a heating means which heats the dielectric window by using radiant ray; and a cooling means which cools the dielectric window.

Preferably, the plasma processing apparatus may further include: a temperature detecting means which detects a temperature of the dielectric window; and a control means which controls the heating means and/or the cooling means, in response to the temperature detected by the temperature detecting means.

Preferably, the temperature detecting means may include a plurality of sensors, and the dielectric window may be divided into a plurality of sections and at least one sensor may be disposed in each of the plurality of sections of the dielectric window.

Preferably, the heating means may include a plurality of heaters which are disposed to face a side surface of the dielectric window, wherein the plurality of heaters are controlled by the control means, wherein each of the plurality of heaters heats a circumferential portion of the dielectric window by using the amount of generated heat that is set independently for each of the plurality of heaters.

Preferably, the plasma processing apparatus may further include a window which is disposed between the heating means and the dielectric window to block the microwave and transmit the radiant ray of the heating means.

Preferably, the cooling means may include an inlet and an outlet of a heat medium which are disposed in each of the plurality of sections of the dielectric window.

Particularly preferably, the cooling means may be controlled by the control means, and makes the heat medium flow at a flow rate that is set independently for each of the plurality of sections of the dielectric window.

Preferably, a holding member for holding the heating means may include a temperature regulating means for maintaining the holding member at a predetermined temperature.

A plasma processing method according to a second aspect of the present invention includes maintaining a holding member for holding a heating means at a constant temperature by using a temperature regulating means while plasma processing is being performed on at least one object to be processed.

A mechanism for regulating a temperature of a dielectric window according to a third aspect of the present invention includes: a heating means which heats the dielectric window by using radiant ray; a cooling means which cools the dielectric window; a temperature detecting means which detects a temperature of the dielectric window; and a control means which controls the heating means and/or the cooling means, in response to the temperature detected by the temperature detecting means.

Preferably, the temperature detecting means may include a plurality of sensors, and the dielectric window may be divided into a plurality of sections and at least one sensor may be disposed in each of the plurality of sections of the dielectric window.

Preferably, the heating means may include a plurality of heaters which are disposed to face a side surface of the dielectric window, is controlled by the control means, and heats a circumferential portion of the dielectric window by using the amount of generated heat that is independently set for each of the plurality of heaters.

Preferably, the mechanism may further include a window which is disposed between the heating means and the dielectric window to block the microwave and transmit the radiant ray of the heating means.

Preferably, the cooling means may include an inlet and an outlet for a heat medium which are disposed in each of the plurality of sections of the dielectric window.

More preferably, the cooling means may be controlled by the control means, and make the heat medium flow at a flow rate that is independently set for each of the plurality of sections of the dielectric window.

### ADVANTAGEOUS EFFECTS

By using a plasma processing apparatus, a plasma processing method, and a mechanism for regulating a temperature of a dielectric window according to the present invention, a better plasma processing characteristic can be achieved by making it uniform a temperature distribution of the dielectric window used for plasma processing.

### BRIEF DESCRIPTION OF THE DRAWINGS

FIG. 1 is a schematic view showing a configuration of a plasma processing apparatus according to an embodiment of the present invention.

FIG. 2 is a plan view obtained by seeing a cooling block from the outside of a processing container.

FIG. 3 is a perspective view showing a structure of a holding ring.

FIG. 4A is an enlarged cross-sectional view of the holding ring.

FIG. 4B is a partial plan view obtained by seeing the holding ring from a dielectric window side.

FIG. 5 is a perspective view showing a structure of a lamp heater.

FIG. 6 is a plan view of a radial line slot antenna.

FIG. 7 is a view showing an embodiment of temperature control of the dielectric window (temperature control using the cooling block).

FIG. 8 is a view showing an embodiment of temperature control of the dielectric window (temperature control using the holding ring).

FIG. 9 is a view showing characteristics of three types of heating devices (short-wavelength infrared ray, medium-wavelength infrared ray, and carbon (far infrared ray)).

### EXPLANATION ON REFERENCE NUMERALS

1: plasma processing apparatus

2: processing container (chamber)

3: dielectric window (shower plate)

3a: cover plate

3b: base plate

3c: nozzle aperture

3d: groove

3e: gas flow path

4: antenna

4a: waveguiding portion

4b: radial line slot antenna (RLSA)

4c: wavelength-shortening plate

5: waveguide

5a: outer waveguide

5b: inner waveguide

6: cooling block

6a: cooling flow path

7: substrate holder

8a: exhaust port

8b: vacuum pump

9: high frequency power source

11: gate

12: lower container

15: holding ring (upper plate)

15a: protrusion portion

16: temperature sensor

17: cover

18: gas supply device

18a: gas flow path

40a, 40b: slot

150: bolt groove

151: lamp heater

157: hole

157a: through-hole

158: flow path

159a: heat medium inlet

159b: heat medium outlet

171a: inlet

171b: outlet

500: chiller unit

521, 522: heater

531, 532: manifold

541b, 542b: flow rate regulating valve

601, 602: temperature controller

S: space

W: substrate to be processed

### BEST MODE FOR CARRYING OUT THE INVENTION

Hereinafter, a plasma processing apparatus according to embodiments of the present invention will be explained in detail with reference to the drawings. Also, the same or like elements are denoted by the same or like reference numerals in the drawings, and a repeated explanation thereof will not be given.

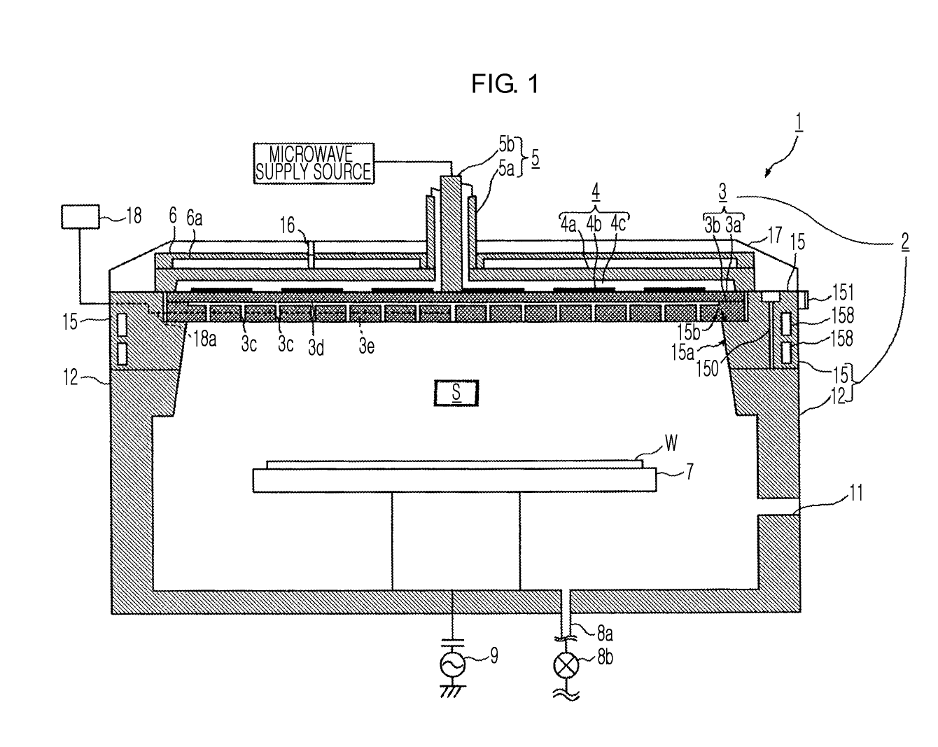

As shown in FIG. 1, a plasma processing apparatus 1 includes a processing container (chamber) 2, an antenna 4, a waveguide 5, a cooling block 6, a substrate holder 7, an exhaust port 8a, a vacuum pump 8b, a high frequency power source 9, a gate 11, temperature sensors 16, a cover 17, and a gas supply device 18.

The processing container 2 includes a lower container 12, a holding ring (upper plate) 15, and a dielectric window (shower plate) 3.

The processing container 2 is configured to be able to be airtightly sealed. A pressure in the processing container 2 can be maintained at a predetermined value by sealing the processing container 2. Also, plasma generated in the processing container 2 can be sealed in the processing container 2 by sealing the processing container 2.

The lower container 12 is formed of a metal such as Al or the like. A protective film formed of aluminum oxide or the like, for example, by oxidation treatment is formed on an inner wall surface of the lower container 12. Also, the substrate holder 7 is attached to a bottom portion inside the lower container 12.

The holding ring (upper plate) 15 is formed of a metal such as Al or the like. A protective film formed of aluminum oxide or the like, for example, by oxidation treatment is formed on an inner wall surface of the holding ring (upper plate) 15. The holding ring (upper plate) 15 is attached onto the lower container 12. The holding ring 15 has a concentric stepped portion (protrusion portion 15a) whose ring diameter (inner diameter) is increased toward a ceiling side of the processing container 2. A stepped portion (flat portion 15b) connected with the protrusion portion 15a supports a circumferential portion of a bottom surface of the dielectric window 3.

Also, the holding ring 15 includes thereinside a plurality of heating devices (here, lamp heaters 151) which are means for heating the circumferential portion of the dielectric window 3 from a side surface of the dielectric window 3. Also, the holding ring 15 includes thereinside flow paths 158. Overheating of the holding ring 15 is prevented by making a heat medium flow in the flow paths 158.

The dielectric window 3 is formed of a dielectric material, such as SiO₂, Al₂O₃, or the like, which transmits a microwave. The dielectric window 3 transmits a microwave supplied from the antenna 4 into the processing container 2. Also, the dielectric window 3 is engaged with the holding ring 15 and also acts as a cover of the processing container 2.

The dielectric window (shower plate) 3 includes a cover plate 3a and a base plate 3b. The base plate 3b includes a plurality of nozzle apertures 3c, a concave groove 3d, and a gas flow path 3e. The nozzle apertures 3c, the groove 3d, and the gas flow path 3e communicate with one another. In a state where the cover plate 3a is attached to the base plate 3b, a process gas supplied from the gas supply device 18 passes through the gas flow path 3e and the groove 3d, and is supplied from the nozzle apertures 3c to a space S right under the dielectric window 3 to have a uniform density distribution.

The antenna 4 includes a waveguiding portion 4a, a radial line slot antenna (RLSA) 4b, and a wavelength-shortening plate 4c. The antenna 4 is coupled to the dielectric window 3. In detail, the radial line slot antenna 4b of the antenna 4 is in close contact with the cover plate 3a of the dielectric window 3. The waveguiding portion 4a is formed of a shield member integrated with the cooling block 6, and the wavelength-shortening plate 4c is formed of a dielectric material such as SiO₂, Al₂O₃, or the like. The wavelength-shortening plate 4c is disposed between the waveguiding portion 4a and the radial line slot antenna 4b, and shortens a wavelength of a microwave.

The waveguide 5 is connected to the antenna 4. The waveguide 5 is a coaxial waveguide including an outer waveguide 5a and an inner waveguide 5b. The outer waveguide 5a is connected to the waveguiding portion 4a of the antenna 4. The inner waveguide 5b is coupled to the radial line slot antenna 4b.

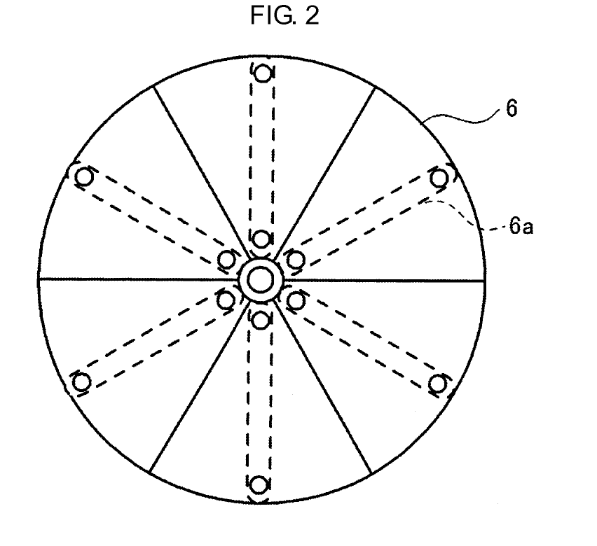

The cooling block 6 (so-called cooling jacket) is disposed on the antenna 4. The cooling block 6 includes thereinside a plurality of cooling flow paths 6a for a heat medium. In order to improve cooling efficiency, the cooling block 6 is integrally formed with the waveguiding portion 4a. Since a heat medium cooled to a predetermined temperature flows in the cooling flow paths 6a, overheating of the dielectric window 3 or the antenna 4 is prevented. The cooling flow paths 6a are uniformly formed over an entire area inside the cooling block 6. For example, if the cooling block 6 has a disk shape corresponding to a shape of the antenna 4, a plurality of cooling flow paths 6a are radially arranged at regular intervals to connect a central portion with a circumferential portion of the cooling block 6 as shown in FIG. 2.

A necessary number of temperature sensors 16 are provided around the waveguide 5. The temperature sensors 16 detect a temperature of the shower plate 3, the antenna 4, and so on. The temperature sensors 16 are, for example, fiber sensors or the like.

The cover 17 is attached to cover an entire top of the processing container 2 including the antenna 4 and the cooling block 6.

Next, an operation of the plasma processing apparatus 1 will be explained. When plasma processing is performed, the inside of the processing container 2 is depressurized by the vacuum pump 8b to be in a vacuum state. A substrate W to be processed is fixed to the substrate holder 7.

An inert gas such as argon (Ar), xenon (Xe), nitrogen (N₂), or the like, and if necessary, a process gas, for example, C5F8 or the like, are supplied from the gas supply device 18 to a gas flow path 18a. The gas passes through the gas flow path 3e and the groove 3d, and is supplied from the nozzle apertures 3c to the space S right under the dielectric window 3 to have a uniform density distribution.

A microwave is supplied from a microwave source through the waveguide 5. Then, the microwave passes through a space between the waveguiding portion 4a and the radial line slot antenna 4b in a radial direction, and is radiated from slots of the radial line slot antenna 4b.

The supplied microwave excites the gas supplied to the space S to generate plasma. As such, plasma processing can be performed on the substrate W to be processed held on the substrate holder 7. Examples of processing performed by the plasma processing apparatus 1 may include formation of an insulating film on the substrate W to be processed by using so-called CVD (Chemical Vapor Deposition) or the like. A set of processes, in which a substrate W to be processed is transferred in when the plasma processing is finished and is transferred out after being processed, are repeated, thereby performing predetermined substrate processing on a predetermined number of substrates.

When the plasma processing is performed, heat is accumulated in the dielectric window 3 and thus the dielectric window 3 and the circumferential portion of the dielectric window 3 are heated to a high temperature. Accordingly, the dielectric window 3 formed of a dielectric material such as SiO₂, Al₂O₃, or the like and the holding ring 15 formed of a material such as Al or the like are undesirably thermally expanded. A thermal expansion coefficient of the holding ring 15 formed of Al or the like is greater than a thermal expansion coefficient of the dielectric window 3 formed of a dielectric material such as SiO₂, Al₂O₃, or the like. Accordingly, as temperature increases, a gap between the side surface of the dielectric window 3 and the holding ring 15 increases.

Although the dielectric window 3 is cooled by the cooling flow paths 6a in order to prevent overheating, a temperature of the dielectric window 3 is generally maintained at about 160 to 170° C. due to heat generated when plasma is formed. Meanwhile, in order to prevent a deposit from being attached on a wall portion of the holding ring 15 surrounding the space S, a temperature of the holding ring 15 is generally regulated to range from 120 to 130° C. At this time, there is a temperature difference of about 30 to 50° C. between the dielectric window 3 and the holding ring 15. Accordingly, heat moves from the dielectric window 3 having a higher temperature toward the holding ring 15.

The movement of the heat occurs mainly on the circumferential portion of the bottom surface of the dielectric window 3 which directly contacts the holding ring 15. As a result, there is a temperature difference between a central portion of the dielectric window 3 and the circumferential portion of the dielectric window 3. The temperature difference causes a density distribution of plasma generated in the space S to be skewed or causes thermal strain of the dielectric window 3.

Here, the lamp heaters 151 which are means for heating the circumferential portion of the dielectric window 3 from the side surface of the dielectric window 3 are disposed inside the holding ring 15. Since the lamp heaters 151 heat the circumferential portion of the dielectric window 3 from the side surface of the dielectric window 3, a uniform temperature distribution of the dielectric window 3 in a radial direction is achieved. As such, the temperature difference in the dielectric window 3 is solved, and the skewed density distribution of the plasma generated in the space S and the thermal strain of the dielectric window 3 are prevented.

Also, the cooling block 6 is installed on the antenna 4 that is one of heat generating portions in the plasma processing apparatus 1. The dielectric window 3 is cooled via the radial slot antenna 4b. Since the dielectric window 3 and the antenna 4 are simultaneously cooled, cooling is efficiently performed. Also, other portions in the device can be prevented from being excessively cooled.

Also, a plurality of the cooling flow paths 6a of the cooling bock 6 which are cooling means, a plurality of the lamp heaters 151 which are heating means, of the holding ring 15, and a plurality of the temperature sensors 16 which are temperature detecting means are provided. Temperatures detected by the temperature sensors 16 are reflected on a control means. Since the control means controls each of a plurality of cooling means and a plurality of heating means independently, a temperature distribution in the dielectric window 3 can become more uniform.

Also, one or more temperature detecting means for detecting temperatures of the holding ring 15 may be provided in addition to the temperature sensors 16. The control means controls a plurality of cooling means and a plurality of heating means, in response to a temperature of each portion detected by each of the temperature detecting means. As such, more precisely, the entire plasma processing apparatus 1 is maintained at a predetermined temperature with a uniform temperature distribution.

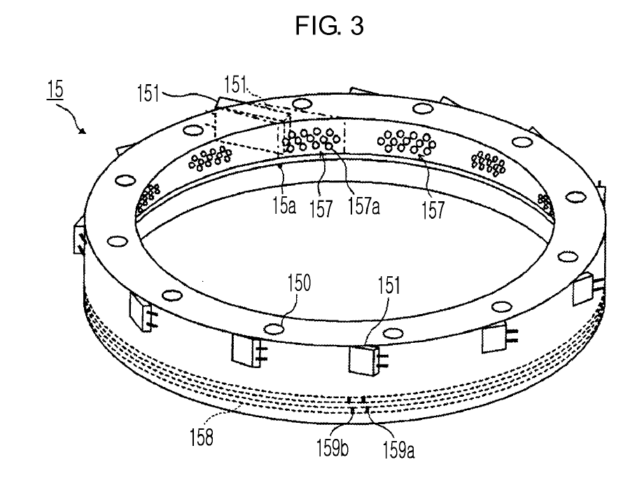

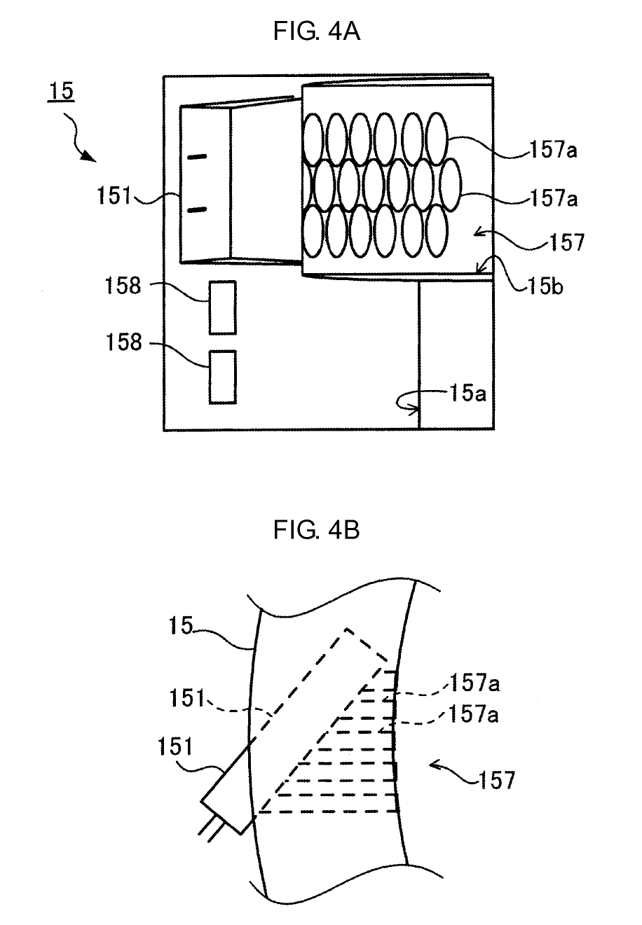

Next, a structure of the holding ring 15 will be explained in detail with reference to FIGS. 3, 4A, and 4B. As shown in FIG. 3, the holding ring 15 includes the lamp heaters 151 as heating means, and the flow paths 158 as cooling means. The heating means heat the circumferential portion of the dielectric window 3. The cooling means cool the holding ring 15 as needed, to regulate the holding ring 15 to a predetermined temperature.

As shown in FIGS. 4A and 4B, bolt grooves 150 for fastening, a plurality of through-holes 157a for the lamp heaters 151 (a group of the through-holes 157a is referred to as a hole 157), and the flow paths 158 for a heat medium are formed in the holding ring 15. The lamp heaters 151 are inserted into grooves for lamp heaters formed in the holding ring 15. Radiant heat emission surfaces of the lamp heaters 151 are disposed near the holes 157.

As shown in FIG. 3, twelve lamp heaters 151 as heating means are arranged at regular intervals with being inserted into the holding ring 15 from the outside of the holding ring 15. The lamp heaters 151 are disposed point-symmetrically about a center of the holding ring 15 and are each inclined by a predetermined angle with respect to a radial direction. The lamp heaters 151 are non-contact infrared heaters, for example, short-wavelength infrared heaters, or may be carbon heaters. The radiant heat emission surfaces of the lamp heaters 151 contact an inner side surface of the holding ring 15.

A plurality of holes 157 are formed in portions of the holding ring 15 contacting the radiant heat emission surfaces of the lamp heaters 151. Each of the holes 157 includes a plurality of through-holes 157a formed close to one another with a predetermined pitch. The holes 157 are disposed in a plurality of places (specifically, a total of 12 places corresponding to the number of the lamp heaters) corresponding to inserted positions of the lamp heaters 151, to allow short-wavelength infrared ray emitted from the lamp heaters 151 to transmit through the through-holes 157a.

Here, it is preferable that a size of each of the through-holes 157a is enough to transmit short-wavelength infrared ray and to block a microwave. That is, it is preferable that each of the through-holes 157a has a diameter greater than a wavelength of short-wavelength infrared ray and less than a wavelength of a microwave. For example, the cylindrical through-holes 157a each having a diameter of 6 mm and a depth of 5 mm are arranged to have a pitch of 6 to 7 mm. In this case, it was confirmed that the through-holes 157a transmitted infrared ray and blocked a microwave.

A shape of each of the through-holes 157 is not limited to the cylindrical shape, and may be a shape having a quadrangular cross-section or a tapered shape whose diameter increases or reduces toward the outside of a frame. In case that each of the through-holes 157 has a tapered shape, it was confirmed that when a minimum value of a diameter of a cross-section of the hole is enough to transmit short-wavelength infrared ray and to block a microwave, the hole transmitted infrared ray and blocked a microwave.

As shown in FIGS. 3 and 4A, two flow paths 158 as cooling means are provided in the holding ring 15. By making a heat medium with a predetermined temperature flow in the flow paths 158, the holding ring 15 is cooled. The heat medium supplied to the flow paths 158 from a heat medium inlet 159a flows in the holding ring 15 and is discharged from a heat medium outlet 159b.

Here, functions of the heating means, the cooling means, and the holes 157 in the holding ring 15 will be explained in detail. When plasma processing is performed in the plasma processing apparatus 1, a temperature of the circumferential portion of the dielectric window 3 is reduced as described above. At this time, when the lamp heaters 151 heat the circumferential portion of the dielectric window 3 from the side surface, a temperature distribution of the dielectric window in the radial direction can be uniform.

The through-holes 157a each have a diameter enough to transmit short-wavelength infrared ray emitted from the lamp heaters 151 and to block a microwave. Here, the through-holes 157a each have a cylindrical shape having a diameter greater than a wavelength of short-wavelength infrared ray and less than a wavelength of a microwave. Accordingly, the short-wavelength infrared ray emitted from the lamp heaters 151 is transmitted through the through-holes 157a. Accordingly, the lamp heaters 151 can directly heat the dielectric window 3 without being hindered by the holding ring 15. Meanwhile, a microwave supplied through the waveguide 5 into the processing container 2 is reflected by an inner wall of the holding ring 15 to be trapped in the frame of the holding ring 15. As such, damage to the microwave can be prevented and the circumferential portion of the dielectric window 3 can be efficiently heated by the lamp heaters 151.

Meanwhile, a heat medium with a predetermined temperature as necessary flows in the flow paths 158 to cool the holding ring 15. At this time, the heat medium supplied from the heat medium inlet 159a to the flow paths 158 flows in the holding ring 15 while depriving of heat, and is discharged from the heat medium outlet 159b. A temperature of the heat medium slowly increases while flowing in the holding ring 15. Accordingly, a temperature difference occurs between the heat medium flowing around the heat medium inlet 159a and the heat medium flowing in the heat medium outlet 159b. As a result, a temperature difference may occur along a circumference of the holding ring 15. As described above, heat moves between the circumferential portion of the dielectric window 3 and the holding ring 15. Accordingly, the temperature difference which may occur along a circumference of the holding ring 15 may cause a temperature distribution of the circumferential portion of the dielectric window 3 to be skewed.

Here, as shown in FIG. 3, a plurality of lamp heaters 151 are arranged at regular intervals along a circumference of the holding ring 15. The control means controls the amount of heat generated by each of the lamp heaters 151 independently, in response to a temperature of each portion of the dielectric window detected by each of a plurality of temperature sensors 16. Since each of the lamp heaters 151 compensates for the temperature difference occurring at the circumferential portion of the dielectric window 3, a temperature distribution of the dielectric window 3 can be more uniform.

Also, preferably, a surface of the holding ring 15 is subjected to mirror-like finishing. The surface of the holding ring 15 having been mirror-like finished reflects the short-wavelength infrared ray emitted from the lamp heaters 151. As such, the lamp heaters 151 can more efficiently heat the dielectric window 3 without hindering cooling of the holding ring 15 by the flow paths 158.

Also, a surface, of the dielectric window 3, facing the lamp heaters 151 through the holes 157, that is, a side wall portion of the dielectric window 3, may be subjected to appropriate surface roughing or may be coated with a material that efficiently absorbs radiant heat emitted from the lamp heaters 151. As such, the circumferential portion of the dielectric window 3 can be more efficiently heated. At this time, it is preferable that the material used to coat the surface does not affect transmission of a microwave.

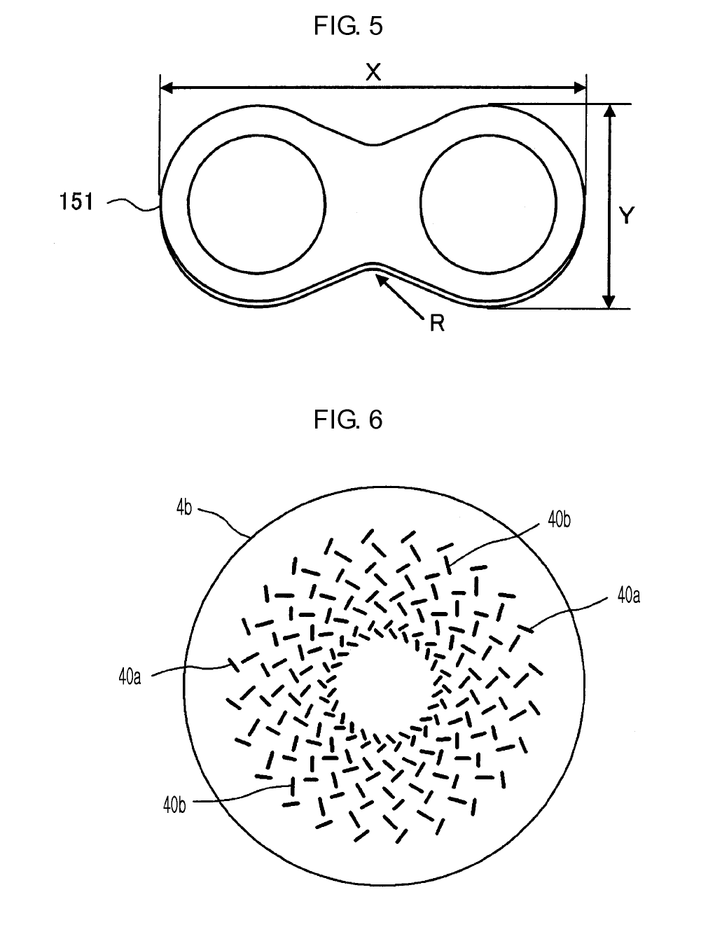

As shown in FIG. 5, the lamp heaters 151 each have a twin tube structure in which one end is connected. A reflective film R (for example, a gold reflective film) is provided at a side opposite to a direction where the infrared ray is emitted so that radiated infrared ray does not exit to the outside.

As shown in FIG. 6, slots 40a and 40b through which a microwave is transmitted are arranged symmetrically in a concentric shape in the radial line slot antenna 4b. The slots 40a and 40b are formed at intervals corresponding to a wavelength of a microwave shortened by the wavelength-shortening plate 4c in a radial direction from a center of the radial line slot antenna 4b, and have a plane of polarization. Also, the slots 40a and the slots 40b are formed to be perpendicular to each other. As a result, a microwave emitted from the slots 40a and 40b forms a circularly polarized wave having two orthogonal polarization components.

Also, although the lamp heaters 151 which are short-wavelength infrared heaters are used as heating means in the embodiment, other short-wavelength infrared heaters may be used. Also, carbon heaters using far infrared ray, heaters using medium-wavelength infrared ray, halogen heaters, or others may be used. Also, heaters which heat resistances such as electrothermal wires or the like, and other non-contact heating devices may be used according to need or the like.

Also, an electronic control device for controlling supply of a process gas or an operation of the high frequency power source is additionally provided in the plasma processing apparatus 1 according to the embodiment of the present invention. Temperature controllers 601 and 602 can communicate with the electronic control device, and thus can perform temperature control based on information from the electronic control device.

According to the plasma processing apparatus 1 according to the embodiment of the present invention, desired uniform substrate processing can be performed in the space S between the dielectric window 3 and the substrate W to be processed. As examples of substrate processing, there are plasma oxidation treatment, plasma nitriding treatment, plasma oxynitriding treatment, plasma CVD treatment, plasma etching treatment, and so on.

Also, when plasma processing is performed, it is preferable that the holding ring 15 is maintained at a constant temperature while at least one substrate is being processed. As such, while one substrate is being processed, thermal strain can be prevented from occurring in the holding ring 15 or the dielectric window 3. As a result, since a microwave introduced into the processing container while the substrate is being processed is prevented from being changed, more uniform plasma processing can be performed. It is preferable that the constant temperature is set to be about a processing temperature. In CVD treatment, the constant temperature is set to be, for example, 150° C. In this case, a film can be suppressed from being attached to the dielectric window 3. In addition, the lower container 12 may be configured to be heated, and at this time, a mechanism for regulating a temperature according to the present invention, which will be described below, may be used.

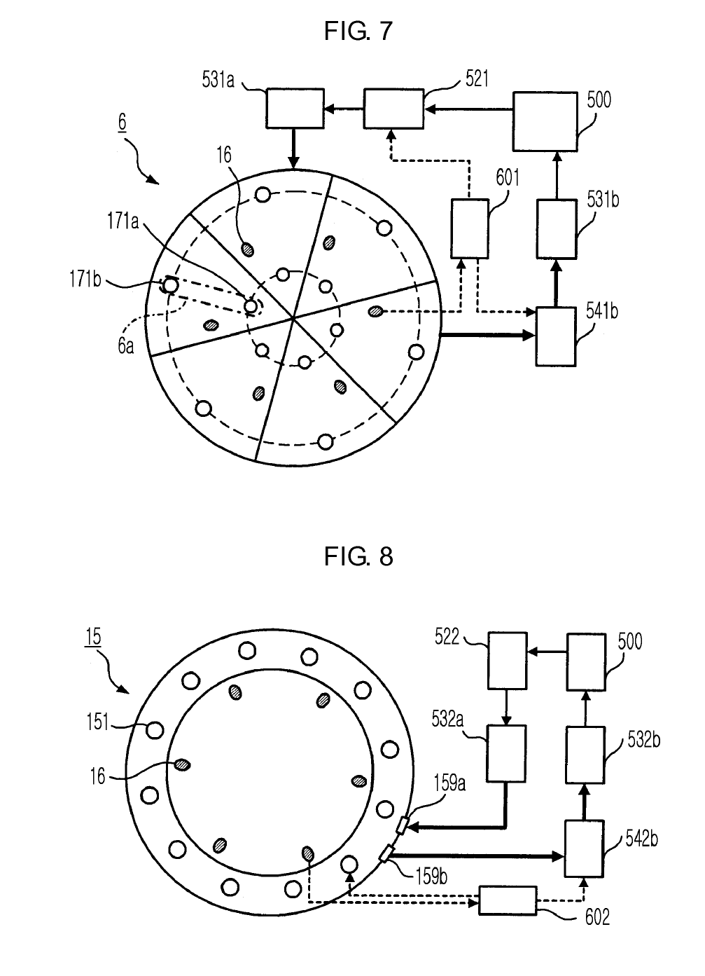

Next, a mechanism for regulating a temperature of a dielectric window according to the present invention will be explained with reference to FIG. 7. The dielectric window corresponds to the dielectric window 3 in the aforesaid plasma processing apparatus according to the present invention. A plasma processing apparatus using the dielectric window 3 is the same as the plasma processing apparatus 1 according to the embodiment of the present invention.

First, an embodiment of cooling control using the cooling block 6 will be explained with reference to FIG. 7. As shown in FIG. 7, the cooling block 6 includes the cooling flow paths 6a, the temperature sensors 16, an inlet 171a of a heat medium, and an outlet 171b of the heat medium. The cooling flow paths 6a, the temperature sensors 16, the inlet 171a of the heat medium, and the outlet 171b of the heat medium are disposed at positions corresponding to six portions obtained by equally dividing the dielectric window 3 in a fan shape. A one-dot-dashed line in FIG. 7 indicates one of the cooling flow paths 6a formed in a radial shape. The other cooling flow paths 6a are not shown for easy understanding.

Since the heat medium flows in the cooling flow paths 6a of the cooling block 6, a temperature of the cooling block 6 is regulated. As a result, a temperature of the antenna 4 contacting a bottom surface of the cooling block 6 and a temperature of the dielectric window 3 contacting a bottom surface of the antenna 4 are regulated.

Each of the cooling flow paths 6a is formed such that the heat medium flows from the inlet 171a formed around a center of an inner side of the antenna 4 toward the outlet 171b formed in a circumferential portion of the antenna 4. The heat medium is supplied from a chiller unit 500. A heater 521 (for example, an electric heater or the like) heats the heat medium to a predetermined temperature. The heat medium heated to the predetermined temperature is distributed to the six cooling flow paths 6a by a manifold 531a. The heat medium having flowed in the cooling flow paths 6a is collected by a manifold 531b. A flow rate of the heat medium flowing in each of the cooling flow paths 6a is regulated by a flow rate regulating valve 541b, through which the heat medium passes before being collected by the manifold 531b. The heat medium is sent from the manifold 531b back to the chiller unit 500. That is, the heat medium cools the dielectric window 3 while circulating between the chiller unit 500 and the cooling flow paths 6a. For example, a liquid-type heat exchange medium such as silicon oil, fluorine-based liquid, ethylene glycol, or the like is used as the heat medium.

Here, as described above, the cooling block 6 includes the temperature sensors 16 disposed at positions corresponding to the six portions obtained by equally dividing the dielectric window 3 in the fan shape. The temperature controller 601 is set to perform temperature control based on temperatures detected by the temperature sensors 16, at every predetermined point of time. The temperature control is performed by the temperature controller 601 independently on each of the portions corresponding to the temperature sensors 16. When the temperature controller 601 sends a command to the flow rate regulating valve 541b to open or close the flow rate regulating valve 541b, a flow rate of a heat medium in each of the cooling flow paths 6a respectively corresponding to the positions of the temperature sensors 16 is controlled. For example, if a temperature detected by one temperature sensor 16 is higher than a temperature detected by another temperature sensor 16, the amount of a heat medium flowing through a portion of a plurality of cooling flow paths 6a corresponding to the one temperature sensor 16 is increased. As a result, more heat is deprived of from a corresponding portion of the cooling block 6, thereby reducing a temperature difference. As such, a temperature of the antenna 4 contacting the bottom surface of the cooling block 6 and a temperature of the dielectric window 3 contacting the bottom surface of the antenna 4 are regulated for every portion, thereby making a temperature distribution uniform. Meanwhile, if all temperatures detected by the temperature sensors 16 are higher or lower than a predetermined temperature, a command for temperature control is sent from the temperature controller 601 to the heater 521 (for example, an electric heater or the like), thereby regulating a temperature of a heat medium.

Also, it is preferable that a shape of the cooling block 6 corresponds to a shape of the antenna 4. It is preferable that a plurality of cooling flow paths 6a of the cooling block 6 are distributed over an entire area. A shape of the cooling flow paths 6a is not limited to the radial shape shown in the present embodiment. Also, the number or places of the cooling flow paths 6a may be arbitrarily set according to a structure of the plasma processing apparatus 1, a type of plasma processing, or the like. It is preferable that the temperature sensors 16 are disposed at positions respectively corresponding to a plurality of cooling flow paths 6a. As such, more precise temperature control of the dielectric window 3 is facilitated.

Alternatively, as a method for cooling the dielectric window 3, cooling flow paths may be provided in an inside of the dielectric window 3 in addition to the cooling block 6. In detail, flow paths in which a heat medium can flow by communicating with the outside are provided in the dielectric window 3. Since the heat medium flows in the flow paths, the dielectric window 3 can be directly cooled. At this time, it is preferable that the flow paths of the heat medium are disposed over the entire dielectric window 3. Since a plurality of cooling means are used together, a temperature rise of the dielectric window 3 is more effectively prevented.

Next, an embodiment of temperature control (heating and cooling) using the holding ring 15 will be explained with reference to the drawings. The holding ring 15 is the same as the holding ring 15 in the plasma processing apparatus according to the embodiment of the present invention shown in FIG. 3. The holding ring 15 includes cooling means and a plurality of heating means. The cooling means cool the holding ring 15. The heating means heat the dielectric window 3. Also, a plurality of temperature sensors 16 are disposed in or around the holding ring 15.

As shown in FIG. 3, two flow paths 158 are provided as cooling means in the holding ring 15. Each of the two flow paths 158 includes the heat medium inlet 159a and the heat medium outlet 159b. A heat medium whose temperature is regulated to a predetermined temperature flows in the flow paths 158, to cool the holding ring 15.

As shown in FIG. 3, the holding ring 15 includes a plurality of lamp heaters 151 as heating means. A plurality of lamp heaters 151 are arranged at regular intervals along a circumference of the holding ring 15.

Also, as shown in FIG. 8, a plurality of temperature sensors 16 are arranged near the holding ring 15. The temperature controller 602 is set to perform temperature control based on temperatures detected by the temperature sensors 16, at every predetermined point of time.

A heat medium flowing in the holding ring 15 is supplied from the chiller unit 500 as shown in FIG. 8. A temperature of the heat medium is regulated to a predetermined temperature by a heater 522 (for example, an electric heater or the like). The heat medium whose temperature is regulated to the predetermined temperature is divided to two branches by a manifold 532a. The heat medium is supplied to the heat medium inlet 159a, passes through each of the flow paths 158, and is discharged from the heat medium outlet 159b. The heat medium passes through the flow rate regulating valve 542b while being divided to two branches, and is collected by a manifold 532b. The collected heat medium is sent back to the chiller unit 500. That is, the heat medium circulates between the chiller unit 500 and the flow paths 158 of the holding ring 15, to cool the holding ring 15. A liquid-type heat exchange medium, for example, silicon oil, fluorine-based liquid, ethylene glycol, or the like, may be used as the heat medium.

As described above, a temperature of a heat medium flowing in the holding ring 15 changes while flowing in the holding ring 15. Accordingly, a temperature difference may occur along the circumference of the holding ring 15. Due to the temperature difference, a temperature difference may also occur along a circumference of the dielectric window 3 in the circumferential portion of the dielectric window 3 supported by the holding ring 15.

Here, a plurality of temperature sensors 16 are disposed near the holding ring 15. A plurality of temperature sensors 16 detect temperatures of corresponding portions, respectively. If a temperature detected by one temperature sensor 16 is lower than a temperature detected by another temperature sensor 16, the temperature controller 602 sends a command to increase the amount of heat generated by one of the lamp heaters 151 corresponding to the one temperature sensor 16. As such, a temperature difference can be prevented from occurring along the circumference of the dielectric window 3.

Meanwhile, all temperatures detected by a plurality of temperature sensors 16 may be higher or lower than a predetermined temperature. For example, when temperatures are controlled to range from 120 to 130° C., a plurality of temperature sensors 16 may detect temperatures exceeding 130° C. In this case, a command to reduce the amount of generated heat is sent from the temperature controller 602 to a plurality of lamp heaters 151. Alternatively, a command to increase the amount of a heat medium flowing in the flow paths 158 may be sent from the temperature controller 602 to the flow rate regulating valve 542b. As such, overheating of the holding ring 15 is prevented.

Also, although the lamp heaters 151 which are short-wavelength infrared heaters are used as heating means in the embodiment, other short-wavelength infrared heaters may be used. Alternatively, far infrared carbon heaters, heaters using medium-wavelength infrared ray, halogen heaters, or the like may be used. Also, heaters heating resistances such as electrothermal wires or the like, or other non-contact heating devices may be used according to need or the like.

### EMBODIMENT

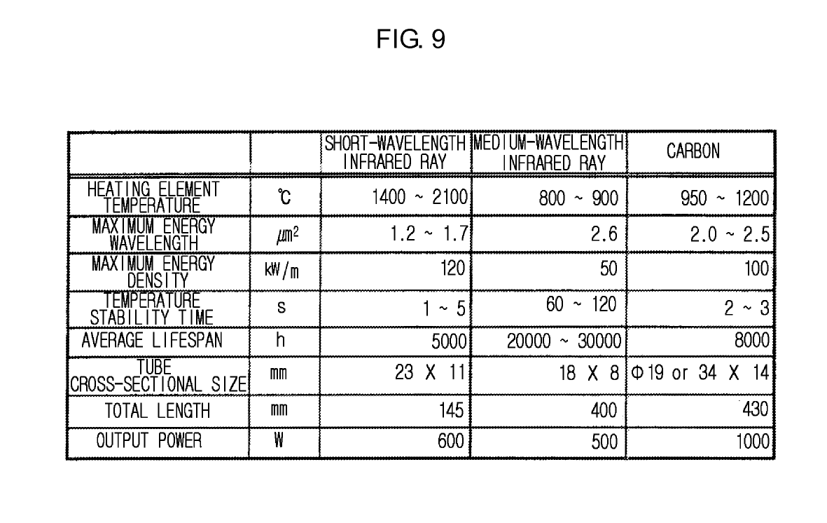

FIG. 9 shows characteristics of three types of heating devices (short-wavelength infrared ray, medium-wavelength infrared ray, and carbon (far infrared ray)). A cross-sectional size of a tube is expressed as the product of X and Y, in the case of the lamp heaters 151 of FIG. 4.

A temperature stability time is related to responsiveness. Since it is easier to control a temperature of a heating device having a shorter temperature stability time, the heating device having the shorter temperature stability time is more suitable. Since a heating device having a longer average lifespan needs a smaller number of exchanges and a shorter maintenance time, the heating device having the longer average lifespan is more preferable. Considering them, it is preferable that a heating means is a heating device using carbon as a heat source. However, since a heating device using carbon as a heat source is large, the heating device may not be suitable for the plasma processing apparatus 1. In this case, a heating device using short-wavelength infrared ray as a heat source, such as the lamp heaters 151 exemplified in the embodiment or the like, may be used.

Also, the plasma processing apparatus and the mechanism for regulating the temperature of the dielectric window explained in the embodiments are exemplary, and the present invention is not limited thereto. A plasma processing method, a gas used in plasma processing, a material and a shape of a dielectric window, heating and cooling means, a method of arranging the heating and cooling means, a type of a substrate to be processed, and so on may be arbitrarily selected.

This application claims the benefit of Japanese Patent Application No. 2008-175589 filed on Jul. 4, 2008, the specification, claims, and drawings of which are incorporated herein in its entirety by reference.

1. A plasma processing apparatus comprising:
a processing container which comprises a dielectric window formed of a dielectric material and of which an inside is depressurizable;
an antenna which supplies a microwave into the processing container through the dielectric window;
a gas supply means which supplies a process gas into the processing container;
a heating means which heats the dielectric window by using radiant ray; and
a cooling means which cools the dielectric window.

2. The plasma processing apparatus of claim 1, further comprising:
a temperature detecting means which detects a temperature of the dielectric window; and
a control means which controls the heating means and/or the cooling means, in response to the temperature detected by the temperature detecting means.

3. The plasma processing apparatus of claim 2, wherein the temperature detecting means comprises a plurality of sensors, and the dielectric window is divided into a plurality of sections and at least one sensor is disposed in each of the plurality of sections of the dielectric window.

4. The plasma processing apparatus of claim 3, wherein the heating means comprises a plurality of heaters which are disposed to face a side surface of the dielectric window,
wherein the plurality of heaters are controlled by the control means,
wherein each of the plurality of heaters heats a circumferential portion of the dielectric window by using the amount of generated heat that is set independently for each of the plurality of heaters.

5. The plasma processing apparatus of claim 1, further comprising a window which is disposed between the heating means and the dielectric window to block the microwave and transmit the radiant ray of the heating means.

6. The plasma processing apparatus of claim 2, further comprising a window which is disposed between the heating means and the dielectric window to block the microwave and transmit the radiant ray of the heating means.

7. The plasma processing apparatus of claim 3, further comprising a window which is disposed between the heating means and the dielectric window to block the microwave and transmit the radiant ray of the heating means.

8. The plasma processing apparatus of claim 4, further comprising a window which is disposed between the heating means and the dielectric window to block the microwave and transmit the radiant ray of the heating means.

9. The plasma processing apparatus of claim 4, wherein the cooling means comprises an inlet and an outlet for a heat medium which are disposed in each of the plurality of sections of the dielectric window.

10. The plasma processing apparatus of claim 9, wherein the cooling means is controlled by the control means, and makes the heat medium flow at a flow rate that is set independently for each of the plurality of sections of the dielectric window.

11. The plasma processing apparatus of claim 4, wherein a holding member for holding the heating means comprises a temperature regulating means for maintaining the holding member at a predetermined temperature.

12. A plasma processing method maintaining a holding member for holding a heating means at a constant temperature by using a temperature regulating means while plasma processing is being performed on at least one object to be processed.

13. A mechanism for regulating a temperature of a dielectric window, the mechanism comprising:
a heating means which heats the dielectric window by using radiant ray;
a cooling means which cools the dielectric window;
a temperature detecting means which detects a temperature of the dielectric window; and
a control means which controls the heating means and/or the cooling means, in response to the temperature detected by the temperature detecting means.

14. The mechanism of claim 13, wherein the temperature detecting means comprises a plurality of sensors, and the dielectric window is divided into a plurality of sections and at least one sensor is disposed in each of the plurality of sections of the dielectric window.

15. The mechanism of claim 14, wherein the heating means
comprises a plurality of heaters which are disposed to face a side surface of the dielectric window,
is controlled by the control means, and
heats a circumferential portion of the dielectric window by using the amount of generated heat that is set independently for each of the plurality of heaters.

16. The mechanism of claim 13, further comprising a window which is disposed between the heating means and the dielectric window to block the microwave and transmit the radiant ray of the heating means.

17. The mechanism of claim 14, further comprising a window which is disposed between the heating means and the dielectric window to block the microwave and transmit the radiant ray of the heating means.

18. The mechanism of claim 15, further comprising a window which is disposed between the heating means and the dielectric window to block the microwave and transmit the radiant ray of the heating means.

19. The mechanism of claim 15, wherein the cooling means comprises an inlet and an outlet for a heat medium which are disposed in each of the plurality of sections of the dielectric window.

20. The mechanism of claim 19, wherein the cooling means is controlled by the control means, and makes the heat medium flow at a flow rate that is set independently for each of the plurality of sections of the dielectric window.
